(19) United States
(12) Patent Application Publication
(10) Pub. No.: US 2009/0239751 A1
(43) Pub. Date: Sep. 24, 2009

(54) ELECTRICAL CONNECTION STRUCTURE FOR A SUPERCONDUCTIVE ELEMENT

(76) Inventors: Nicolas Lallouet, Fiennes (FR); Sebastien Delplace, Loon-Plage (FR)

Correspondence Address: SOFER & HAROUN LLP., 317 MADISON AVENUE, SUITE 910, NEW YORK, NY, 10017, US

(21) Appl. No.: 12/372,884

(22) Filed: Feb. 18, 2009

(30) Foreign Application Priority Data
Mar. 20, 2008 (FR) 08 51793

(51) Int. Cl. H01L 39/02; H01B 12/00

(52) U.S. Cl. 505/163; 174/125.1

(57) ABSTRACT

The invention relates to a high voltage electrical connection structure for a superconductive element cooled by a cryogenic fluid in a cryostat and connected to an electrical bushing that passes through at least one enclosure at ambient temperature, said bushing comprising a central conductor having its top end connected by means of a connection arrangement to a connection part extending to outside the enclosure at ambient temperature and passing through a top wall of said enclosure, said central conductor being surrounded over the major fraction of the length by an electrically insulating sheath fastened rigidly to the bottom wall of said enclosure at ambient temperature. According to the invention, said connection arrangement comprises a conductive part mounted on said top end at ambient temperature of the central conductor and a plurality of deformable conductive elements connected to said conductive part and to said connection part, said conductive part having a cylindrical wall surrounding said conductive elements and forming a screen relative to the electric field.

### RELATED APPLICATION

This application claims the benefit of priority from French Patent Application No. 08 51793, filed on Mar. 20, 2008, the entirety of which is incorporated by reference.

### BACKGROUND

1. Field of the Invention

The present invention relates to an electrical connection structure for a superconductive element, such as a cable conveying electricity under medium or high voltage. The structure serves to connect the end of the superconductive element that is at cryogenic temperature to equipment that is at ambient temperature, usually in air.

2. Description of Related Art

Because of the large temperature difference between the superconductive element and the equipment for connecting thereto, i.e. between the cryogenic temperature that may be about −200° C. and ambient temperature, it is necessary to interpose a connection structure between the superconductive element and the equipment so that the temperature transition is performed while minimizing thermal losses as much as possible, and while simultaneously complying with electrical constraints, e.g. due to the high voltage if the element is a cable. The structure then comprises an electrical bushing made up mainly of a central conductor surrounded by an insulating sheath for conveying electricity from the superconductive cable to an outlet connection at ambient temperature. This structure needs to be of reasonable length and it must perform the temperature transition while ensuring that losses by thermal conduction are small, so as to avoid boiling the cryogenic liquid that cools the cable and/or so as to avoid increasing the cost of cooling the cable.

One such structure is described in patent document EP 1 703 610 and it is shown in longitudinal section in FIG. 1.

It comprises a superconductive cable 30 cooled by a cryogenic fluid 31, e.g. liquid nitrogen, that is contained in a cryostat 33. The zone designated by reference 36 is at cryogenic temperature, which for so-called “high temperature” superconductors is about −200° C.

The top end of the superconductive cable is connected to the bottom end 38 of an electrical bushing 39. The bushing is constituted mainly by a central conductor 40 of copper or aluminum alloy, having an electrically insulating sheath 41 molded around it, e.g. a sheath made of epoxy. The outside surface of the insulating sheath is covered in a layer of electrically conductive material, e.g. by metal plating.

The inside and outside walls of the cryostat are extended vertically to form the side walls of an intermediate enclosure 45. The intermediate enclosure is filled with a solid material presenting low thermal conductivity. This material is preferably in the form of a foam, such as a polyurethane foam or a cellular glass foam. The temperature of the zone 47 is intermediate between cryogenic temperature and ambient temperature.

Above the intermediate enclosure 45, an enclosure 48 at ambient temperature is fastened on a plate 46. The electrical bushing 39 passes through this top wall 46 in leaktight manner with the help of a fastening and sealing flange, and it extends to the outside of the enclosure 49 through the top wall 50 of said enclosure at ambient temperature. The side wall of the enclosure is constituted by an electrical insulator 51, e.g. an epoxy resin reinforced with glass fibers. The enclosure 48 at ambient temperature is filled up to a level 53 with a liquid 54 that is a good electrical insulator, such as silicone oil. In addition to providing good electrical insulation for the electrical bushing 39, the liquid 54 makes it easier for the enclosure at ambient temperature to be stabilized thermally. The zone 55 is thus at a temperature close to ambient temperature.

The electrically insulating sheath 41 is fastened in rigid and leaktight manner by the flange to the horizontal wall between the cryostat 43 and the intermediate enclosure 45. The electrically insulating sheath 41 is also sealed to the horizontal top wall 46 between the intermediate enclosure 45 and the enclosure 48 at ambient temperature.

The central conductor 40 does not have any electrically insulating sheath 41 at its top end, and outside the enclosure 48 at ambient temperature it is connected to a connection terminal 58 in order to supply electricity under medium or high voltage to the superconductive cable or in order to feed equipment at ambient temperature with electricity under medium or high voltage coming from the superconductive cable 30.

The invention relates to this connection at the top end of the central conductor.

This conductor may have a length of more than 2.5 meters above the cryogenic fluid, and given manufacturing tolerances on the various assembly parts and the rigid fastening of the electrically insulating sheath by flanges, it is found to be difficult to obtain accurate alignment of the bushing 39 through the various assembly elements 45, 46, 48, and 50 so that the end of the conductor 40 takes up a position at the connection terminal 58 that is on the longitudinal axis of the structure.

It is then harmful to apply force to the bushing in order to put it into place since the bushing might be damaged. Furthermore, since the bushing 39 is surrounded over the major fraction of its length by the electrically insulating sheath, this assembly of a conductor and its sheath is very rigid and is flexible to a very small extent.

Furthermore, the conductor may shrink vertically under the influence of the relatively low temperature to which it is subjected in the structure, in particular in the bottom zones 36 and 47. Its top end can thus move downwards in translation, giving rise to a disconnection.

It is known elsewhere to accommodate this problem of shrinkage by subdividing a conductor of a superconductive element cooled by a cryogenic fluid into a large number of adjacent conductive strands that are optionally twisted together, as described in patent document WO 02/29930.

### OBJECT AND SUMMARY OF THE INVENTION

More precisely, the invention solves mechanical assembly problems by proposing a connection arrangement for the top end at ambient temperature between the conductor and the connection terminal, which arrangement allows the position of said end freedom to move in three dimensions.

To do this, the invention provides a high voltage electrical connection structure for a superconductive element cooled by a cryogenic fluid in a cryostat and connected to an electrical bushing that passes through at least one enclosure at ambient temperature, said bushing comprising a central conductor having its top end connected by means of a connection arrangement to a connection part extending to outside the enclosure at ambient temperature and passing through a top wall of said enclosure, said central conductor being surrounded over the major fraction of the length by an electrically insulating sheath fastened rigidly to the bottom wall of said enclosure at ambient temperature, wherein said connection arrangement comprises a conductive part mounted on said top end at ambient temperature of the central conductor and a plurality of deformable conductive elements connected to said conductive part and to said connection part, said conductive part having a cylindrical wall surrounding said conductive elements and forming a screen relative to the electric field.

Thus, by deforming the conductive elements, it is possible to connect them both to the conductive part and to the connection part, even if these two parts are off-center relative to each other, and, to a lesser extent, even if the conductor shrinks vertically.

In a preferred embodiment, said conductive elements are metal braids.

Preferably, said braids are regularly distributed around the longitudinal axis of the conductor.

Advantageously, said braids are engaged and soldered in said conductive part.

Advantageously, said braids are engaged and soldered in said connection part.

Said conductive part may be made of copper.

Said conductive elements may be made of copper.

Preferably, said connection part is a conductive bar having an annular flange in which said conductive elements are connected.

Preferably, an intermediate enclosure is interposed between said cryostat and said enclosure at ambient temperature, and said electrically insulating sheath is fastened rigidly to the bottom wall of said intermediate enclosure.

### BRIEF DESCRIPTION OF THE DRAWINGS

The invention is described below with the help of figures that merely show a preferred embodiment of the invention.

FIG. 1, described above, is a longitudinal section view of a known superconductive structure.

FIG. 2 is a fragmentary longitudinal section view of a superconductive structure in accordance with the invention.

FIG. 3 is a perspective view of a connection arrangement of a superconductive structure in accordance with the invention.

FIG. 4 is a perspective view in section on IV-IV of a connection arrangement of a superconductive structure in accordance with the invention.

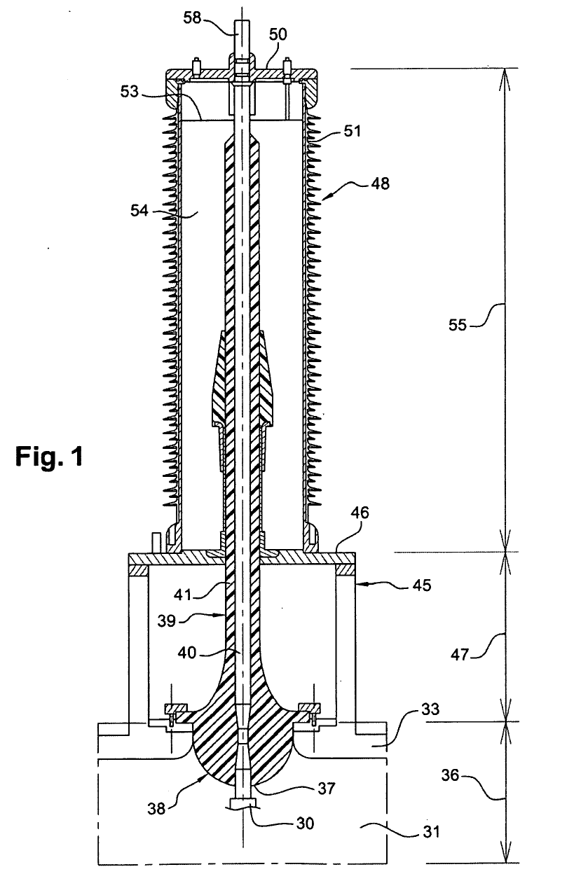

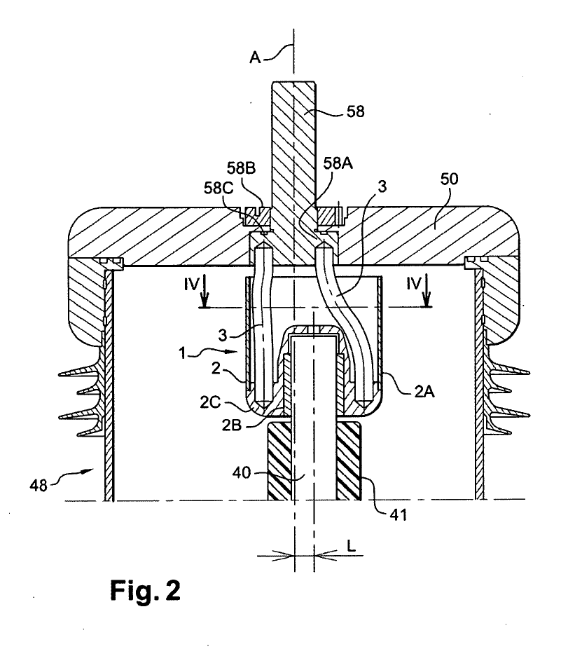

FIG. 2 shows the top portion of a connection structure of the type described above.

### MORE DETAILED DESCRIPTION

The central conductor 40 thus does not have an electrically insulating sheath 41 at its top end and it is connected outside the enclosure at ambient temperature 48 to a connection terminal 58 that passes through the top wall 50 of the enclosure. The superconductive cable is thus fed with electricity under medium or high voltage, or equipment at ambient temperature is thus fed with electricity under medium or high voltage coming from the superconductive cable.

To make the connection between the central conductor 40 and the connection terminal 58, the top end of the conductor is connected by means of a connection arrangement 1 to the terminal 58, which more generally can be referred to as a connection part, and which goes to the outside of the enclosure 48 at ambient temperature by passing through the top wall 50 of the enclosure, being fastened thereto by screws 58B, for example, with a sealing gasket 58C being interposed to seal the enclosure from the outside environment.

This connection arrangement 1 comprises a conductive part 2, preferably made of copper, that is mounted on the top end of the conductor 40 with an interposed multi-contact ring 2B and a plurality of deformable conductive elements 3 that are connected to the conductive part 2 via their bottom ends and to the connection part 58 via their top ends, the conductive part 2 having a cylindrical wall 2A surrounding the conductive elements 3.

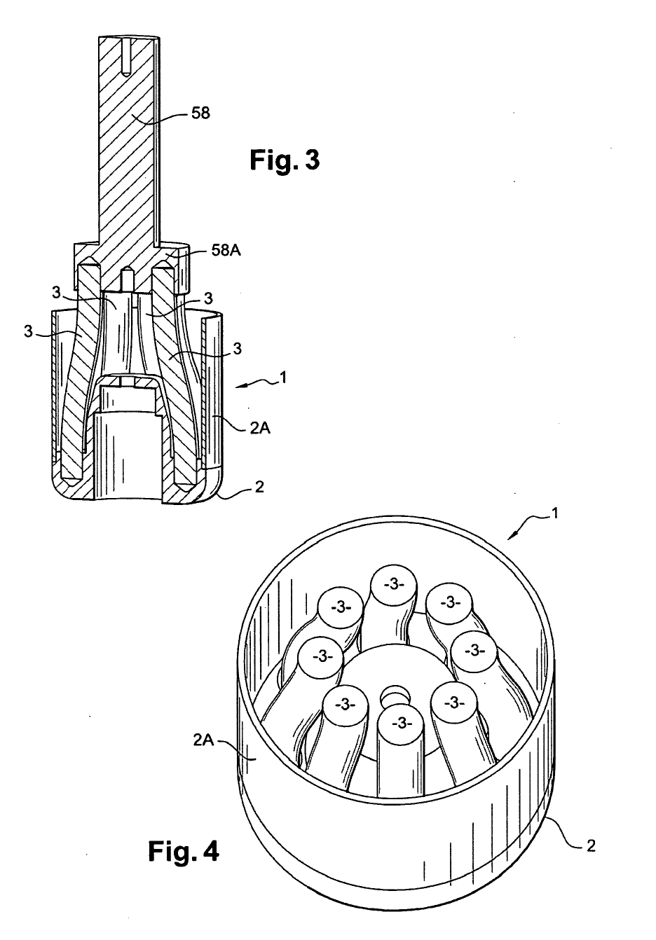

FIGS. 3 and 4 also show this connection element in detail.

The conductive elements are cylindrical metal braids, preferably made of copper, and of relatively large section, of the order of 250 square millimeters (mm²) per braid, and they are regularly distributed around the longitudinal axis of the conductor. In the example shown, there are eight of them. Their bottom ends are engaged in the conductive part 2 and their top ends are engaged in the connection part 58 and they are silver-soldered thereto. More precisely, the connection part 58 is a conductive bar having an annular flange 58A into which the top ends of the braid are engaged.

The conductive part 2 is made up of two portions, a bottom portion 2C for connection to the conductor 40 and a cap forming the cylindrical wall 2A that is soldered to the first bottom part 2C. The cap 2A protects the braids 3 that might otherwise give rise to problems of high voltage breakdown in the presence of the cap.

Because of the great capacity of the braids 3 for deforming, this connection arrangement 1 enables the conductor 40 to be connected electrically to the connection part 58 without running the risk of applying stresses to those two elements. This applies even if the conductor 40 is off-center relative to the longitudinal axis A of the structure, as represented by distance L in FIG. 2, and/or if the conductor 40 shrinks vertically under the influence of relatively low temperatures in the bottom portion of the structure. The arrangement in accordance with the invention thus ensures a connection that is good in spite of the conductor 40 moving in three dimensions.

What is claimed is:

1. A high voltage electrical connection structure for a superconductive element cooled by a cryogenic fluid in a cryostat, and connected to an electrical bushing that passes through at least one enclosure at ambient temperature, the bushing having a central conductor having its top end connected by means of a connection arrangement to a connection part extending to outside the enclosure at ambient temperature and passing through a top wall of said enclosure, the central conductor being surrounded over the major fraction of the length by an electrically insulating sheath fastened rigidly to the bottom wall of said enclosure at ambient temperature, said electrical connection arrangement comprising:
a conductive part mounted on said top end at ambient temperature of the central conductor; and
a plurality of deformable conductive elements connected to said conductive part and to said connection part, said conductive part having a cylindrical wall surrounding said conductive elements and forming a screen relative to the electric field.

2. A structure according to the preceding claim, wherein said conductive elements are metal braids.

3. A structure according to claim 2, wherein said braids are regularly distributed around the longitudinal axis of the conductor.

4. A structure according to claim 2, wherein said braids are engaged and soldered in said conductive part.

5. A structure according to claim 2, wherein said braids are engaged and soldered in said connection part.

6. A structure according to claim 1, wherein said conductive part is made of copper.

7. A structure according to claim 1, wherein said conductive elements are made of copper.

8. A structure according to claim 1, wherein said connection part is a conductive bar having an annular flange in which said conductive elements are connected.

9. A structure according to claim 1, wherein an intermediate enclosure is interposed between said cryostat and said enclosure at ambient temperature, and wherein said electrically insulating sheath is fastened rigidly to the bottom wall of said intermediate enclosure.
